(19) United States
(12) Patent Application Publication
(10) Pub. No.: US 2011/0290746 A1
(43) Pub. Date: Dec. 1, 2011

(54) SLIDE ASSEMBLY

(75) Inventor: WEN-HU LU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/879,366

(22) Filed: Sep. 10, 2010

(30) Foreign Application Priority Data
May 27, 2010 (CN) 201010184729.0

(51) Int. Cl. H05K 5/02; A47B 96/00

(52) U.S. Cl. 211/26; 211/183

(57) ABSTRACT

A slide assembly is used for mounting a server. The slide assembly includes a slide and a mounted device. The slide includes a retaining portion. The retaining portion includes a holding member. The mounting device is pivotably attached to the retaining portion. The mounting device includes a spring element and a locking portion. An end of the spring element abuts the holding member. The mounting device is capable of being rotated relative to the retaining portion from a securing position to a release position. In the securing position, the locking portion extends past the retaining portion. In the release position, the spring element is elastically deformed and the locking portion is rotated away from the retaining portion.

### BACKGROUND

1. Technical Field

The present disclosure relates to slide assemblies, especially to a slide assembly mounted to a server rack.

2. Description of Related Art

Certain computer systems, such as computer network systems, typically include many separate computer units or servers that are positioned and stacked relative to each other in a rack. The rack includes a plurality of support columns, where each computer server is secured to opposing slide assemblies attached to the columns. The slide assemblies allow the servers to be pulled away from the front of the rack so that each separate server can be serviced by technicians for various reasons, such as maintenance, replacement of computer cards, etc., while the server is still in operation.

Known slide assemblies generally include a stationary member having a front bracket and a rear bracket. The front bracket is rigidly secured to a front column of the rack, and the rear bracket is rigidly secured to a corresponding rear column of the rack. The inner most slidable member is secured to a sidewall of the server. When the technician grasps the server and pulls it away from the rack, the slidable members slide relative to the stationary member allowing the server to be extended out of the rack.

The support columns include holes and the front and rear brackets include associated pins. The pins are inserted into the desired holes in the columns to align and hold the slide assembly. Various devices and techniques are known in the art to secure the slide assembly to the columns so that they are securely affixed thereto. These known techniques are sometimes complicated, requiring installation tools and the like to perform the mounting procedure. Additionally, certain techniques use loose hardware, such as screws and bolts that may be lost and are inconvenient to keep track of.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a rack and a slide assembly.

FIG. 2 is an exploded, partial, enlarged view of the slide assembly.

FIG. 3 is an exploded view of a mounting device of FIG. 2, but shown from another aspect.

FIG. 4 is an assembled view of FIG. 2.

FIG. 5 is an assembled view of FIG. 1.

FIG. 6 is a partial front view of FIG. 5.

FIG. 7 is a partial top view of FIG. 5, of the mounting device.

FIG. 8 is similar to FIG. 7, but shows the mounting device locked.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

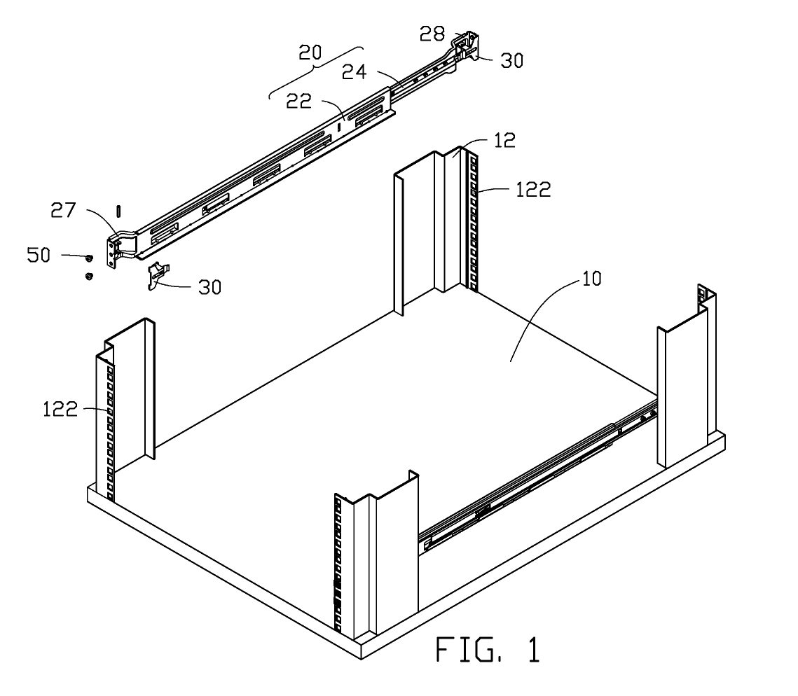

Referring to FIG. 1, one embodiment of a slide assembly 20 is used for mounting a server. The slide assembly 20 includes a rack 10 and telescopically mounted first slide 22 and second slide 24, and two mounting devices 30 mounted to the first slide 22 and the second slide 24 respectively. The rack 10 includes two pairs of opposite stand columns 12. Each pair of stand columns 12 can receive one slide assembly 20. A plurality of vertically arranged and evenly spaced rectangular through holes 122 is defined in each stand column 12.

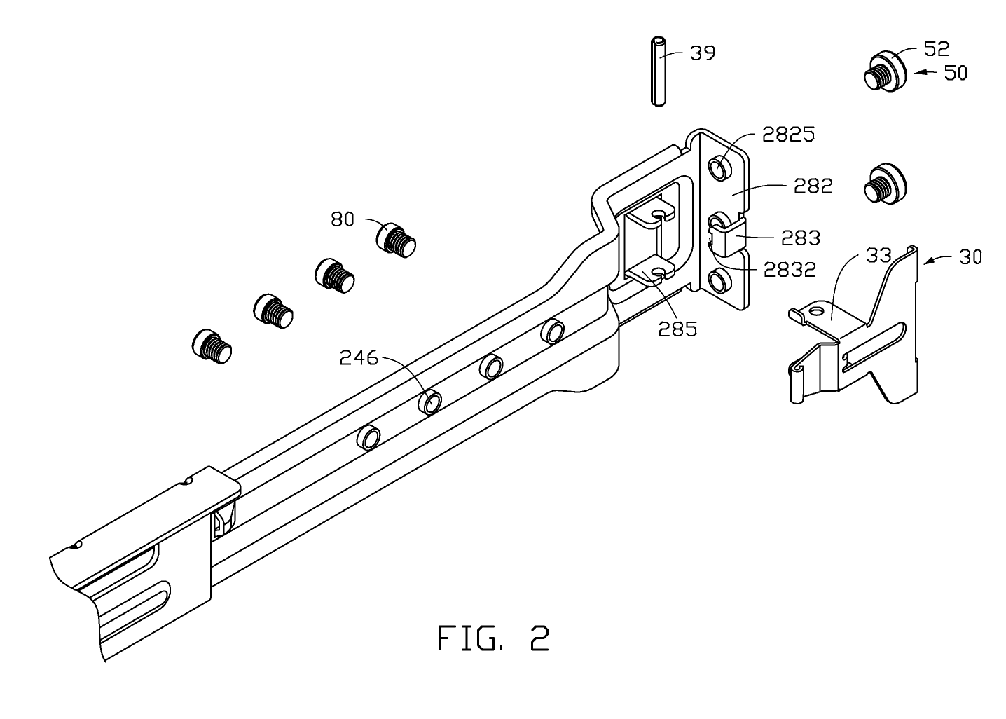

Referring to FIG. 2, the first slide 22 includes a U-shaped first retaining portion 27 at one end. A receiving space is defined in the first retaining portion 27 for receiving the mounting device 30. The second slide 24 includes a U-shaped second retaining portion 28, which has substantially the same structure as the first retaining portion 27. The second retaining portion 28 includes a base plate, two first pivot portions 285 perpendicular to the base plate, an end plate 282 and a holding member 283. Two pivot holes are defined in the two first pivot portions 285 for receiving a resilient post 39. The post 39 has a substantially C-shaped cross section. The end plate 282 is perpendicular to the base plate. A number of retaining holes 2825 are defined in the end plate 282 for receiving at least one fastener 50. The fastener 50 has a head portion 52. The head portion 52 can extend through the through hole 122 of the stand column 12. The holding member 283 extends from one side of the end plate 282. The holding member 283 is substantially L-shaped. A recess 2832 is defined at a distal end of the holding member 283.

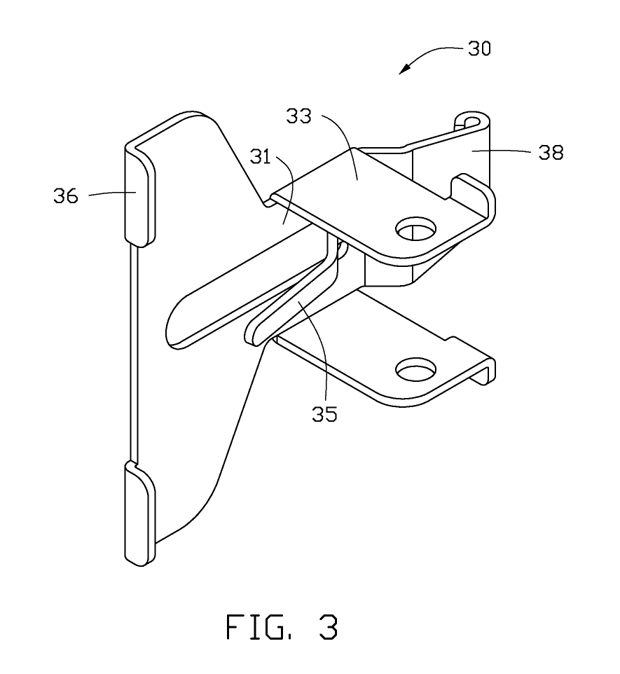

Referring to FIG. 3, the mounting device 30 includes a main body 31, two second pivot portions 33, a pressing portion 38 and two locking portions 36. The two second pivot portions 33 extend from the main body 31. Two pivot holes are defined in the second pivot portions 33 for receiving the post 39. The locking portions 36 are located on one distal end of the main body 31. The press portion 38 is located on opposite sides of the locking portions 36. The press portion 38 has a curled knuckle end portion. An elongated spring element 35 obliquely extends from the main body 31.

A number of mounting holes 246 are defined in the second slide 24 for receiving a number of remaining fasteners 80. The remaining fasteners 80 have varied heads in size from the fastener 50 to accommodate stand columns with different sized through holes.

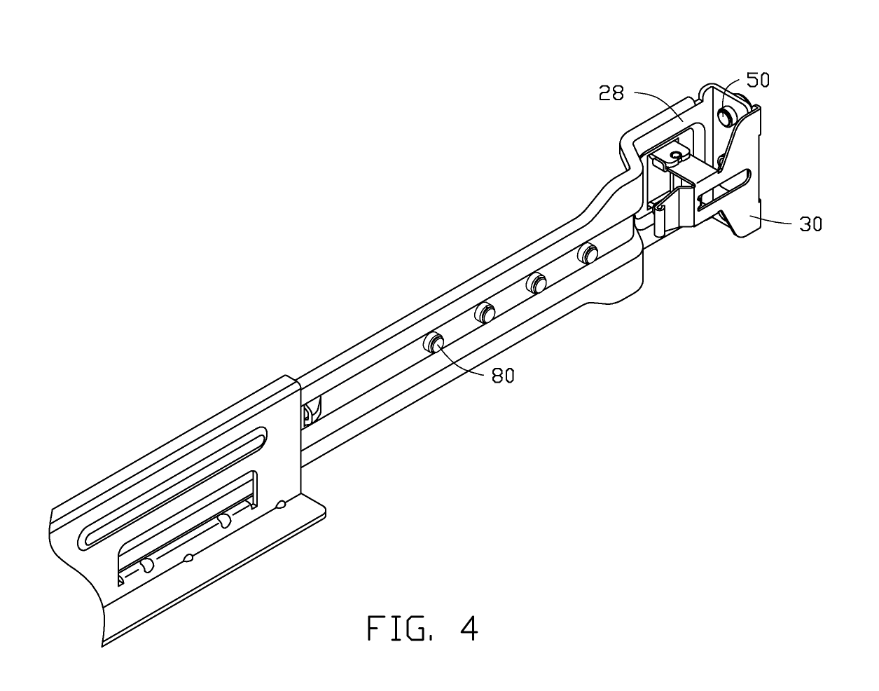

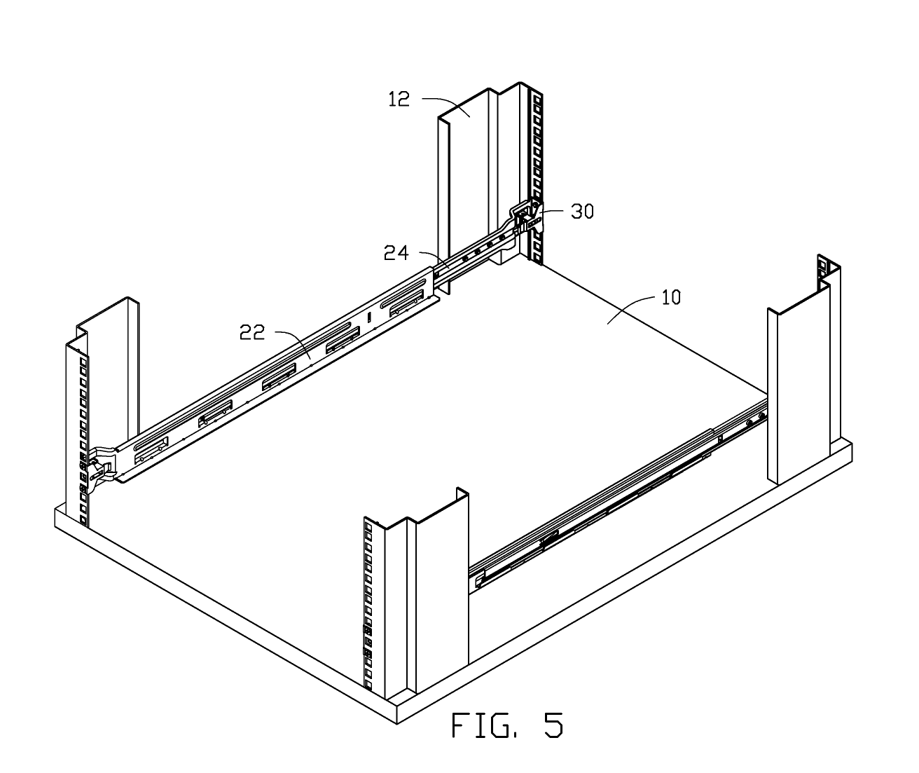

Referring to FIG. 4 and FIG. 5, during assembly, the first slide 22 and the second slide 24 are telescopically mounted to each other. The mounting device 30 is placed in the receiving space of the retaining portion 28. The first pivot portions 285 of the second retaining portion 28 and the second pivot portions 33 of the mounting device 30 are aligned. The post 39 extends through the first pivot portions 285 and the second pivot portions 33 to mount the mounting device 30 to the second slide 24. The fasteners 50 are fixed to the end plate 282. In the same way, the first slide 22 is assembled with another mounting device 30 and other fasteners 50. The remaining fasteners 50 are also mounted to the second slide 24.

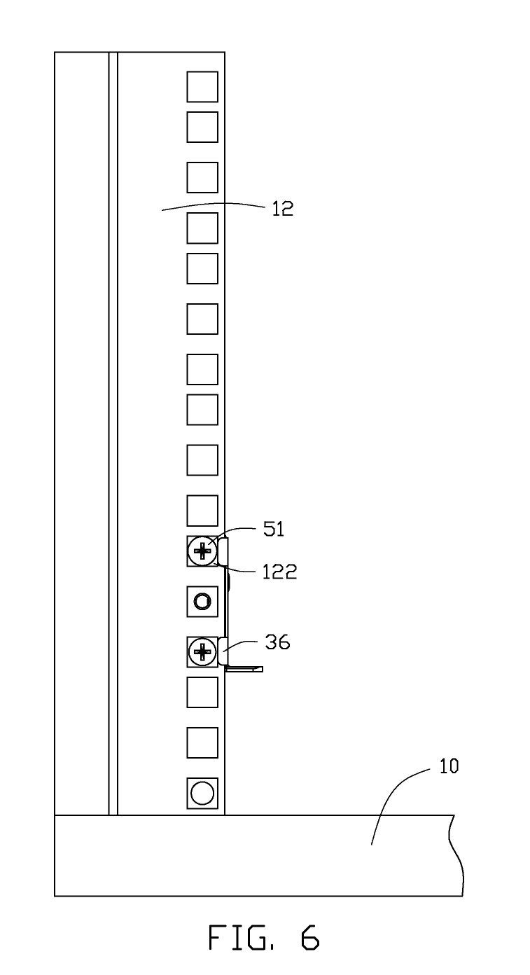

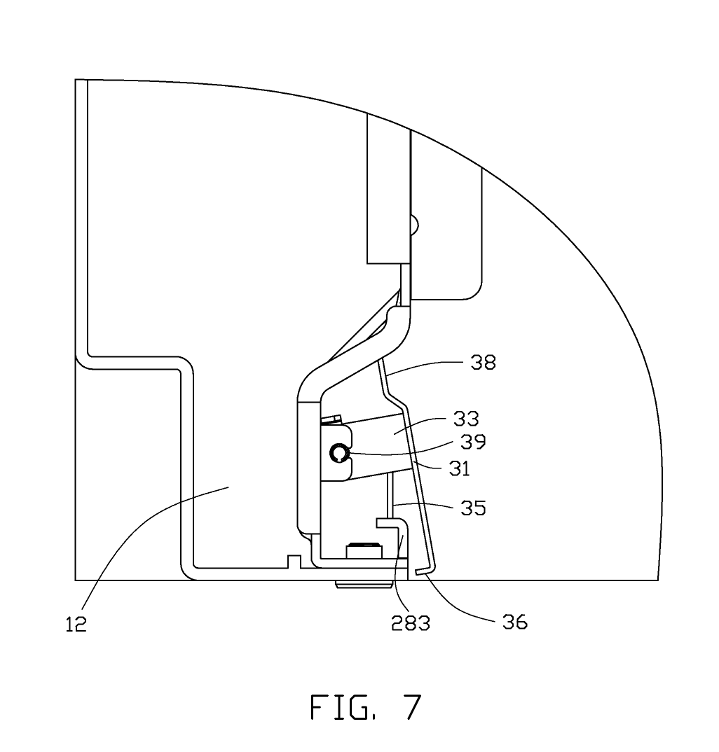

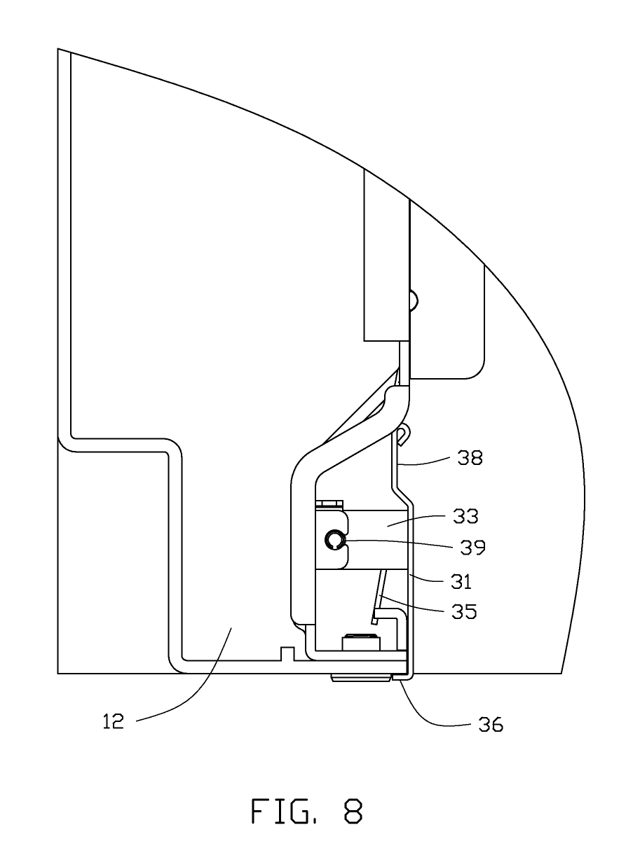

Referring through FIG. 6 to FIG. 8, the first slide 22 and the second slide 24 are adjusted to reach the opposite stand columns 12. The press portion 38 is pressed inward. An end of spring element 35 abuts against the distal end of the holding member 283 in the recess 2832, and the spring element 35 elastically distorts. The fasteners 50 of the first slide 22 and the second slide 24 are respectively inserted into the through holes 122 of the stand column 12. The fasteners 50 restrict movement of the second slide 24 in a plane defined by the end plate 282. The press portion 38 is released, and the spring element 35 straightens back out. The locking portions 36 clasps an outer side of the stand column 12 and prevents the second slide 24 from moving along a direction substantially perpendicular to the end plate 282. The second slide 24 is fixed to the stand column 12. The first slide 22 is fixed to the opposite stand column 12 in the same way.

It is also understood, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A slide assembly comprising:
a slide, the slide comprising a retaining portion, the retaining portion comprising a holding member; and
a mounting device pivotably attached to the retaining portion, the mounting device comprising a spring element and a locking portion, wherein an end of the spring element abuts the holding member, wherein the mounting device is capable of being rotated relative to the retaining portion from a securing position, where the locking portion extends past the retaining portion, to a release position, where the spring element is elastically deformed and the locking portion is rotated away from the retaining portion.

2. The slide assembly of claim 1, wherein the mounting device is capable of pivoting about a resilient post, and the resilient post has a C-shaped cross section.

3. The slide assembly of claim 1, wherein the mounting device further comprises a pressing portion, and the pressing portion has a curled end portion.

4. The slide assembly of claim 1 further comprising a fastener, wherein the fastener is mounted to the retaining portion.

5. The slide assembly of claim 4, wherein the retaining portion further comprises an end plate, the fastener is mounted to the end plate and restricts movement of the slide in a plane defined by the end plate, and the locking portion prevents the slide from moving along a direction substantially perpendicular to the plane.

6. The slide assembly of claim 4 further comprising a remaining fastener, wherein the remaining fastener has a head having different size than a head of the fastener.

7. The slide assembly of claim 1, wherein the holding member is substantially L-shaped.

8. The slide assembly of claim 7, wherein a recess is defined in the holding member, and the end of the spring element is received in the recess.

9. The slide assembly of claim 1, wherein the mounting device further comprises a main body, and the spring element is elongated and extends obliquely to a plane defined by the main body.

10. The slide assembly of claim 1, wherein a U-shaped receiving space is defined in the retaining portion, and the mounting device is received in the U-shaped receiving space.

11. A slide assembly for mounting a server, the slide assembly comprising:
a rack, the rack comprising two opposite stand columns;
two slides telescopically mounted to each other, the two slides mounted to the two stand columns at opposite ends thereof, at least one of the slides comprising a retaining portion, and the retaining portion comprising a holding member; and
a mounting device pivotably attached to the retaining portion, the mounting device comprising a spring element and a locking portion, wherein an end of the spring element abuts the holding member, the mounting device is capable of being rotated relative to the retaining portion from a securing position, where the locking portion extends past the retaining portion, to a release position where the spring element is elastically deformed and the locking portion is rotated away from the retaining portion.

12. The slide assembly of claim 11, wherein the mounting device is capable of pivoting about a resilient post, and the resilient post has a C-shaped cross section.

13. The slide assembly of claim 11, wherein the mounting device further comprises a pressing portion, and the pressing portion has a curled end portion.

14. The slide assembly of claim 11 further comprising a fastener, wherein the fastener is mounted to the retaining portion, and a through hole is defined in the one of the two stand column, and the fastener is inserted into the through hole.

15. The slide assembly of claim 14, wherein the retaining portion further comprises an end plate, the fastener is mounted to the end plate and restricts movement of the slide in a plane defined by the end plate, and the locking portion prevents the slide from moving along a direction substantially perpendicular to the end plate.

16. The slide assembly of claim 14, wherein the fastener has a head coupled to the through hole, and the slide further comprising a remaining fastener, wherein the remaining fastener has a head in different size from a head of the fastener.

17. The slide assembly of claim 11, wherein the holding member is substantially L-shaped.

18. The slide assembly of claim 17, wherein a recess is defined in the holding member, and the end of the spring element is received in the recess.

19. The slide assembly of claim 11, wherein the mounting device further comprises a main body, and the spring element is elongated and extends obliquely to a plane defined by the main body.

20. The slide assembly of claim 11, wherein a U-shaped receiving space is defined in the retaining portion, and the mounting device is received in the U-shaped receiving space.
